(19) United States
(12) Patent Application Publication
(10) Pub. No.: US 2026/0004039 A1
(43) Pub. Date: Jan. 1, 2026

(54) INTEGRATED CIRCUIT FLOORPLAN GENERATION USING GENERATIVE ARTIFICIAL INTELLIGENCE MODELS

(71) Applicant: QUALCOMM Incorporated, San Diego, CA (US)

(72) Inventors: Payal AGARWAL, Bengaluru (IN); Rishubh KHURANA, Bengaluru (IN); Andriy TEMKO, Ballincollig (IE); Mysore SRIRAM, Bengaluru (IN)

(21) Appl. No.: 18/759,303

(22) Filed: Jun. 28, 2024

(51) Int. Cl. G06F 30/392; G06F 30/27

(52) U.S. Cl. CPC G06F 30/392; G06F 30/27

(57) ABSTRACT

Certain aspects of the present disclosure provide techniques and apparatus for generating a layout of an integrated circuit using machine learning techniques. An example method generally includes generating a random floorplan including a random arrangement of a plurality of circuit blocks representing components of the integrated circuit. A floorplan representing a candidate layout for the integrated circuit is generated using a generative artificial intelligence model and the random floorplan. Generally, the generative artificial intelligence model may be trained to generate the floorplan based on features associated with the plurality of circuit blocks including one or more geometric conditioning features. The generated floorplan is output for fabricating one or more samples of the integrated circuit.

### INTRODUCTION

Aspects of the present disclosure relate to integrated circuit design.

Integrated circuits (ICs) are electronic circuits that may be designed and fabricated to form a complete processing unit, such as a central processing unit (CPU), graphics processing unit (GPU), neural processing unit (NPU), digital signal processor (DSP), application-specific integrated circuit (ASIC), system-on-a-chip (SoC), or the like. To design an integrated circuit, various software modules can be used to design various components of the integrated circuit. For example, a component of an integrated circuit may be defined as a soft macro that specifies the functionality of the component irrespective of a process by which the integrated circuit will be fabricated, or as a hard macro in which the functionality of the component is tied to a specific fabrication process.

### BRIEF SUMMARY

Certain aspects of the present disclosure provide a method for generating a layout of an integrated circuit using machine learning techniques. The method generally includes generating an initial including an initial arrangement of a plurality of circuit blocks representing components of the integrated circuit. A floorplan representing a candidate layout for the integrated circuit is generated using a generative artificial intelligence model and the initial floorplan. Generally, the generative artificial intelligence model may be trained to generate the floorplan based on features associated with the plurality of circuit blocks including one or more geometric conditioning features. The generated floorplan is output for fabricating one or more samples of the integrated circuit.

Certain aspects of the present disclosure provide a method for training a generative artificial intelligence model to generate a layout of an integrated circuit. The method generally includes accessing a ground-truth data set including a plurality of ground-truth floorplans representing valid candidate designs of integrated circuits, each candidate design including a plurality of circuit blocks associated with one or more geometric conditioning features. A training data set is generated based on distorting floorplans in the plurality of ground-truth floorplans over a period of time. A generative artificial intelligence model is trained to generate floorplans based on the training data set and the ground-truth data set, the floorplans respecting the one or more geometric conditioning features associated with the plurality of circuit blocks. The trained generative artificial intelligence model is deployed.

Other aspects provide processing systems configured to perform the aforementioned methods as well as those described herein; non-transitory, computer-readable media comprising instructions that, when executed by one or more processors of a processing system, cause the processing system to perform the aforementioned methods as well as those described herein; a computer program product embodied on a computer-readable storage medium comprising code for performing the aforementioned methods as well as those further described herein; and a processing system comprising means for performing the aforementioned methods as well as those further described herein.

The following description and the related drawings set forth in detail certain illustrative features of one or more aspects.

### BRIEF DESCRIPTION OF THE DRAWINGS

The appended figures depict only certain aspects of this disclosure and are therefore not to be considered limiting of the scope of this disclosure.

FIG. 1 illustrates the generation of a floorplan representing a layout of an integrated circuit using a generative artificial intelligence model, according to aspects of the present disclosure.

FIG. 2 illustrates an example architecture of a generative artificial intelligence model trained to generate a floorplan representing a layout of an integrated circuit, according to aspects of the present disclosure.

FIGS. 3A and 3B illustrate the generation of a training data set for training a generative artificial intelligence model to generate a floorplan representing a layout of an integrated circuit, according to aspects of the present disclosure.

FIGS. 4A-4C illustrate the training and finetuning of a generative artificial intelligence model for generating a floorplan representing a layout of an integrated circuit, according to aspects of the present disclosure.

FIG. 5 illustrates example operations for generating a floorplan representing a layout of an integrated circuit using a generative artificial intelligence model, according to aspects of the present disclosure.

FIG. 6 illustrates example operations for training a generative artificial intelligence model to generate a floorplan representing a layout of an integrated circuit, according to aspects of the present disclosure.

FIG. 7 depicts an example processing system configured to perform various aspects of the present disclosure.

FIG. 8 depicts an example processing system configured to perform various aspects of the present disclosure.

To facilitate understanding, identical reference numerals have been used, where possible, to designate identical elements that are common to the drawings. It is contemplated that elements and features of one aspect may be beneficially incorporated in other aspects without further recitation.

### DETAILED DESCRIPTION

Aspects of the present disclosure provide apparatus, methods, processing systems, and computer-readable mediums for generating floorplans representing layouts of an integrated circuit using generative artificial intelligence models.

During the development process, integrated circuits may be defined in terms of individual circuits, sub-systems, and/or the full system-on-a-chip (SoC). Generally, these integrated circuits may be defined as a plurality of functional blocks which may be defined as hard or soft macros in electronic design automation tools used to design these integrated circuits. A valid design generally positions the individual functional blocks adjacent to other functional blocks with which the individual functional blocks interact such that the design complies with various power, performance, and area (PPA) specifications defined for the integrated circuit. These PPA specifications may specify, for example, a maximum amount of power used by the integrated circuit, a target level of performance (e.g., in terms of operations per second that can be performed by the integrated circuit, a data bandwidth of the integrated circuit, a maximum clock speed achievable by a given design of the integrated circuit, etc.), and an amount of space occupied by the integrated circuit design. Invalid designs, meanwhile, may include designs in which functional blocks overlap or are not adjacent to functional blocks on the perimeter of the integrated circuit. Further, after placement of these individual functional blocks, the functional blocks may be connected based on connectivity and operational relationships between different functional blocks in a routing process, which includes multiple rules to be followed. Violation of these rules may result in an invalid design, which is generally a design that cannot be manufactured. Further, invalid designs may include otherwise designs that would otherwise be valid (e.g., designs in which functional blocks are on the perimeter of the integrated circuit or adjacent to functional blocks with which other functional blocks interact) but do not comply with the PPA specifications defined for the integrated circuit.

To design an integrated circuit, functional blocks (also referred to as macros), which may be large in size, may be manually placed during the design process in such a way that the relative arrangement of these functional blocks is based on connectivity between these blocks. Further, the arrangement of functional blocks may follow undefined rules, patterns, or styles that prevent the creation of design rule violations that render a design invalid. However, because there are an infinite number of ways in which functional blocks of an integrated circuit can be laid out in a floorplan representing the design of an integrated circuit without knowledge of the undefined rules, patterns, or styles used in designing integrated circuits, automated floorplanning of integrated circuits is typically a computationally complex process (e.g., on the order of nondeterministic polynomial (NP) complexity). To reduce the complexity involved in generating floorplans representing a layout of an integrated circuit, various machine learning-based techniques have been used. For example, annealing techniques, in which the design objectives for an integrated circuit are defined and used in generating candidate layouts, or reinforcement learning techniques in which the outputs of machine learning models (e.g., candidate layouts) are verified by a human, can be used to generate floorplans representing layouts of integrated circuits. However, these techniques may not generate floorplans that reflect how integrated circuits are typically designed, as mathematical definitions of design objectives for an integrated circuit may not allow for generation of floorplans that accurately reflect these design objectives and incorporate the techniques used in manually designing valid floorplans for an integrated circuit. Further, these techniques may use a large number of data samples which may not actually exist.

Aspects of the present disclosure provide techniques for generating floorplans representing candidate layouts for an integrated circuit design using generative artificial intelligence models and geometric conditioning features associated with circuit blocks. As discussed in further detail herein, a generative artificial intelligence model may be trained to generate a floorplan representing a candidate design for an integrated circuit using diffusion techniques in which noise, represented by the positioning of circuit blocks in locations that reflect the techniques used in manually designing valid floorplans for an integrated circuit, is reduced while complying with the geometric conditioning features associated with the circuit blocks in the integrated circuit. By using a generative artificial intelligence model to generate floorplans representing candidate designs for an integrated circuit, aspects of the present disclosure may provide for the generation of valid floorplans that comply with PPA specifications defined for the integrated circuit and reflect human design intuition regarding the positioning of various circuit blocks in a floorplan for the integrated circuit.

### Example Generative Artificial Intelligence Models For Generating Floorplans Representing Layouts of an Integrated Circuit

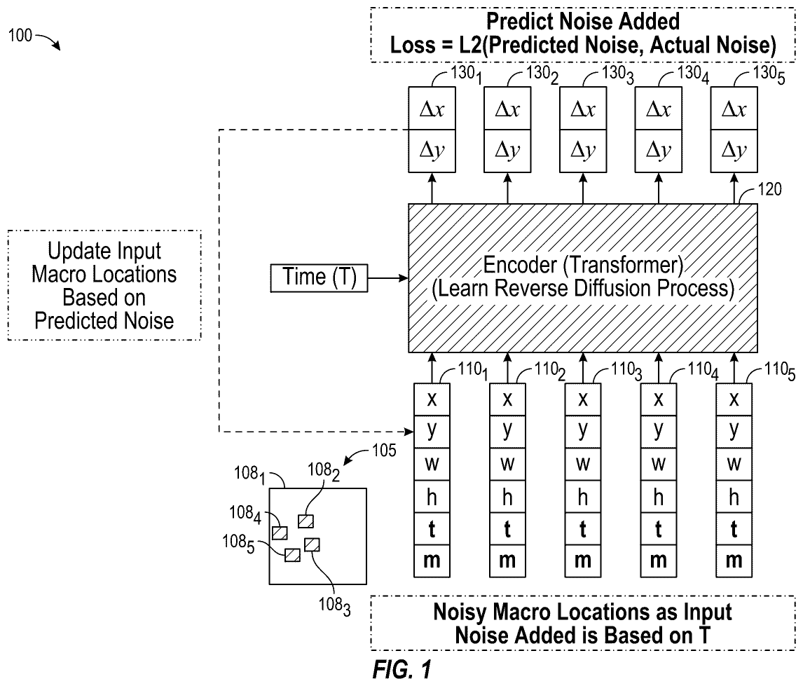

FIG. 1 illustrates an example 100 of generating of a floorplan representing a layout of an integrated circuit using a generative artificial intelligence model, according to aspects of the present disclosure.

As illustrated, to generate a floorplan representing a layout of an integrated circuit, a random floorplan 105 including a plurality of circuit blocks 1081 through 1085 (collectively referred herein as “circuit blocks 108”) represented by the circuit block features 1101 through 1105 (collectively referred to herein as “circuit block features 110”). Generally, the random floorplan 105 may be represented by an overall circuit block (also referred to herein as a “floorplan boundary”) representing the area in which other circuit blocks are positioned and one or more circuit blocks representing different functional components of an integrated circuit. For example, for a floorplan of an SoC, the floorplan may be represented by a floorplan boundary defining an area on which the various components of the SoC are positioned, as well as a plurality of circuit blocks associated with these various components, which may be described by a netlist or other graph of circuit components. These components may include, for example, memory components and cells of logic gates, each of which may be connected by wires in order to implement the SoC. Various combinations of memory components and/or logic gates may compose different larger components of the SoC, such as large (high-performance) processing cores, small (efficiency) processing cores, graphics processing units (GPUs), neural processing units (NPUs), input/output (I/O) ports, caches, registers, or other static random access memory (SRAM) blocks, and the like. In some aspects, these processing cores or units may be composed of a plurality of circuit blocks representing different portions of the processing cores, such as integer math units, floating-point math units, vector/tensor math units, registers in which data is stored for processing, cache units, and the like.

Each circuit block may be represented by a set of circuit block features 110 identifying the positional and geometric characteristics of the circuit block. As illustrated, the circuit block features 110 may include positional information, dimensional information, and geometric conditioning features. The positional information may include the x and y coordinates which correspond to the horizontal and vertical location of a reference point of the circuit block (e.g., a corner of the circuit block). The dimensional information may include the height and width of the circuit block. In some aspects, the height and width of the circuit block may be scaled based on the size of the floorplan boundary on which these additional circuit blocks are to be arranged. The floorplan boundary may, for example, be scaled with one or both of a height dimension or width dimension scaled between −1 and 1, with 0 representing the middle of the circuit block. The height, width, horizontal location, and vertical location features may be appropriately scaled based on the scaling of the dimensions of the circuit block between −1 and 1.

The geometric conditioning features generally include features that define how the transformer model 120 (or other generative artificial intelligence model) adjusts the location of the circuit blocks during each round of inferencing. In some aspects, the geometric conditioning features include a type of the circuit block and whether the circuit block is movable or not movable.

In generating the random floorplan 105, non-movable circuit blocks may be randomly positioned on the boundary of the floorplan of the integrated circuit, which may be represented, as discussed, as a special type of non-movable circuit block on which other circuit blocks representing other components of the integrated circuit are positioned. The features associated with each circuit block of the integrated circuit may be input into the transformer model 120 for processing in order to generate a revised layout including adjustments to the locations of one or more circuit blocks of the integrated circuit. In some aspects, the transformer model 120 may be a diffusion model which denoises an input iteratively, using a reverse diffusion process, to attempt to recover a denoised set of circuit block locations from a noisy input. In this example, a noisy input may be an input which includes circuit blocks that are neither located on the perimeter of the floorplan of the integrated circuit nor adjacent to a circuit block that is located on the perimeter of the floorplan. The output of the transformer model 120 may include an adjustment 130 to the positional information associated with a circuit block in the circuit block features 110. Generally, an adjustment 130 generated by the transformer model 120 may include a Ax and a Ay value representing an adjustment to the horizontal and vertical location in the overall floorplan at which the reference point associated with a circuit block is to be located. The circuit block associated with the floorplan of the integrated circuit and other non-movable circuit blocks may have an adjustment 130 with values of Δx=0 and Δy=0, while circuit blocks associated with geometric conditioning features indicating that the circuit blocks are movable may have an adjustment 130 with any valid value of Δx and/or Δy. Generally, a valid value of Δx and/or Δy may be a value that adjusts a location of a circuit block so that a circuit block does not extend past any edge of the floorplan.

Generally, the transformer model 120 can adjust the locations of one or more circuit blocks of the integrated circuit iteratively. Each iteration (or time step) that the transformer model executes may apply an adjustment to the locations of one or more movable circuit blocks until a valid floorplan is generated that satisfies the geometric constraints defined for an integrated circuit, conditioned on PPA specifications defined for the integrated circuit. In some aspects, the transformer model 120 may generate these floorplans as a guided sampler in which a candidate layout of the integrated circuit is directly sampled from a solution set X* according to the expression [symbol] log(P_{θ}(x)), where X* represents various ground-truth integrated circuit designs representing valid candidate designs for an integrated circuit (e.g., integrated circuit designs in which circuit blocks are located on the perimeter of a floorplan or adjacent to circuit blocks located on the perimeter of the floorplan). Further, the transformer model 120 may bias solutions according to PPA specifications defined for the integrated circuit, such that the sampling of floorplans from the solution set X* is performed according to the expression [symbol] log (P_{θ}(x|y)), where y is in a set of explicit PPA specifications defined for the integrated circuit.

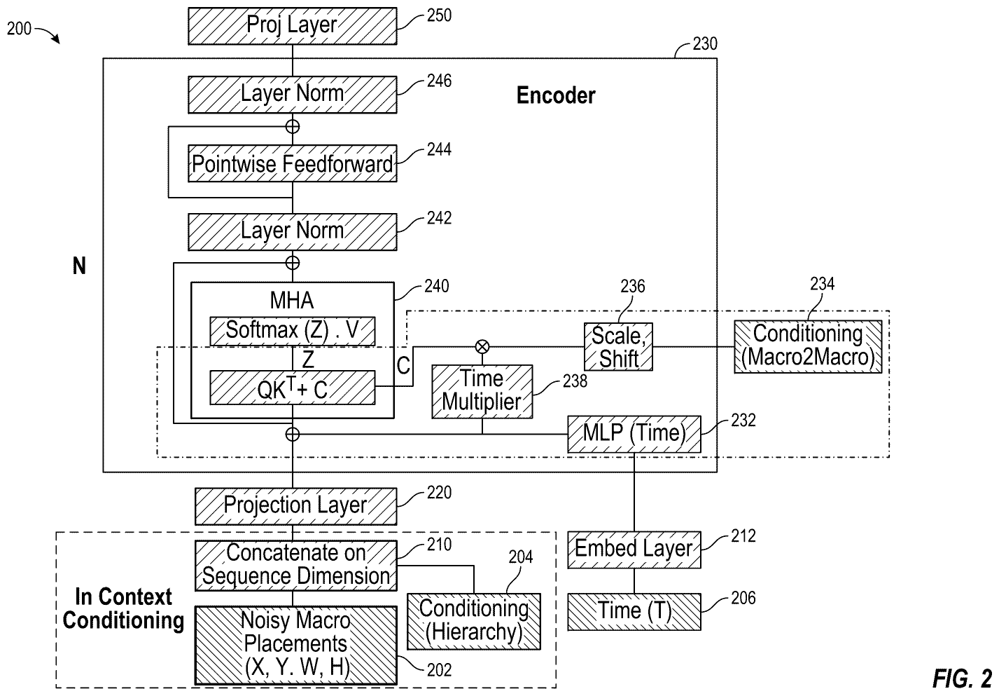

FIG. 2 illustrates an example architecture of a generative artificial intelligence model 200 (e.g., the transformer model 120 illustrated in FIG. 1) trained to generate a floorplan representing a layout of an integrated circuit, according to aspects of the present disclosure.

As illustrated, the generative artificial intelligence model 200 receives an input defining a plurality of circuit blocks included in an integrated circuit design. The input may include macro placement data 202, conditioning features 204, and timing information 206. The macro placement data 202 may represent a noisy image to be denoised using the generative artificial intelligence model 200 and include information defining the location (positional information, in terms of x and y axis location data on a coordinate plane for a reference point defined for the circuit block, such as a corner of a circuit block) and size (dimensional information, in terms of scaled w and h values relative to a larger floorplan boundary) of each circuit block included in the integrated circuit design. The conditioning features 204 may, as discussed above, include information defining a type of a circuit block and whether a circuit block is movable or non-movable. In some aspects, the type of circuit block may be used to identify how to move a circuit block relative to other circuit blocks, as the generative artificial intelligence model 200 may be trained to adjust the locations of circuit blocks in an overall layout of an integrated circuit in a manner similar to that of real-life or simulated integrated circuit designs in which circuit blocks may be positioned adjacent to similar circuit blocks or other related circuit blocks but may be positioned distant from dissimilar circuit blocks (e.g., so that the integrated circuit design meets PPA specifications for the integrated circuit).

The macro placement data 202 and conditioning features 204 may be concatenated at block 210 and projected into a set of query, key, and value data which can be used by the encoder 230 to determine adjustments to apply to the positions of one or more circuit blocks in the integrated circuit design. Meanwhile, the timing information 206, which may represent a number of iterations which have been already executed by the generative artificial intelligence model 200, may be passed through an embedding layer 212 to generate a time embedding that can be used within the encoder to influence the output generated during the next round of inferencing. For example, embeddings representing a smaller amount of elapsed time may allow for the generative artificial intelligence model 200 to perform larger adjustments to the positions of circuit blocks in the integrated circuit, while embeddings representing a larger amount of elapsed time may serve as a constraint on the amount of adjustment which the generative artificial intelligence model 200 can perform on the locations of circuit blocks in the floorplan.

As illustrated, the encoder 230 generates conditioning data which may be added to the query and key information within the multi-head attention (MHA) block 240 to allow for the generation of a floorplan based on the geometric conditioning features associated with the circuit blocks in the floorplan for the integrated circuit. As illustrated, the time embedding generated by the embedding layer 212 may be processed by a time multi-layer perceptron and added to the projection of the macro placement data 202 and the conditioning features 204 to generate a time-conditioned query (Q), key (K), and value (V) projection of the macro placement data 202 and conditioning features 204 for processing by the MHA block 240. The time embedding may also be multiplied at the time multiplier 238 by scaled and shifted conditioning data generated by processing the conditioning data 234 through a scaling and shifting block 236 to generate a conditioning input C. The conditioning data 234 may include various macro-to-macro conditioning features defining spatial (e.g., positional, adjacency, etc.) relationships between different macros. For example, these macro-to-macro conditioning features may include conditioning features such as an amount of overlap between different circuit blocks, LI distance associated with the current floorplan, connectivity information between different circuit blocks, and the like. While FIG. 2 illustrates a single instance of the encoder block 230, it should be understood that the encoder block may be repeated multiple times within the generative artificial intelligence model 200.

Within the MHA block 240, an intermediate value Z may be generated according to the equation QK^{T}+C, where K^{T} represents a transpose of the key data K generated by the projection layer 220. The intermediate value Z may be processed in a nonlinear layer and multiplied by V, according to the equation softmax(Z)·V to generate an attention output of the MHA block 240, which may be combined with the time-conditioned Q, K, and V projection of the macro placement data 202 and conditioning features 204 and processed through a layer normalization block 242, a feedforward network 244, and a layer normalization block 246 to generate an encoded version of an adjusted floorplan (relative to the floorplan represented by the macro placement data 202 and conditioning features 204). The encoded version of the adjusted floorplan may be projected into coordinate data for the adjusted floorplan using the projection layer 250, and the adjusted floorplan may be processed to determine whether to execute subsequent inferencing rounds using the generative artificial intelligence model 200 (e.g., when the adjusted floorplan represented by the output of the projection layer 250 fails to comply with spacing, overlap, and positioning rules defined for a valid example of an integrated circuit design).

The generative artificial intelligence model 200 may be position-invariant. In doing so, the order in which circuit blocks are processed using the generative artificial intelligence model 200 may not impact the final output of the generative artificial intelligence model. By omitting ordering data from the circuit blocks included in the floorplan for an integrated circuit, aspects of the present disclosure may allow for the generative artificial intelligence model 200 to operate on a variety of ordered or unordered inputs defining the various circuit blocks to be included in an integrated circuit.

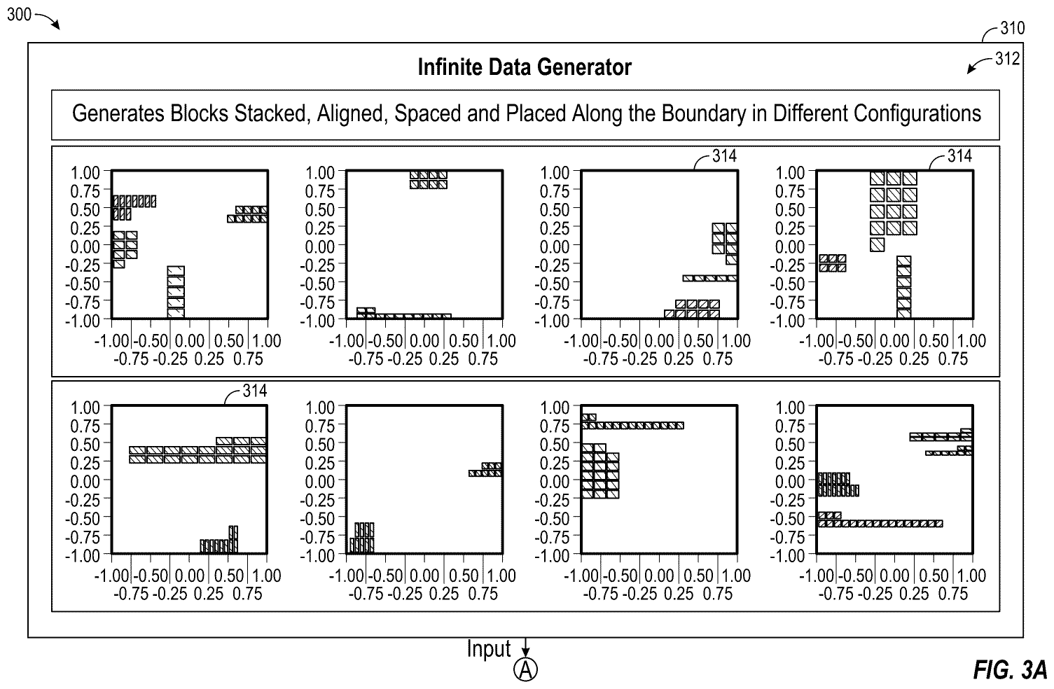

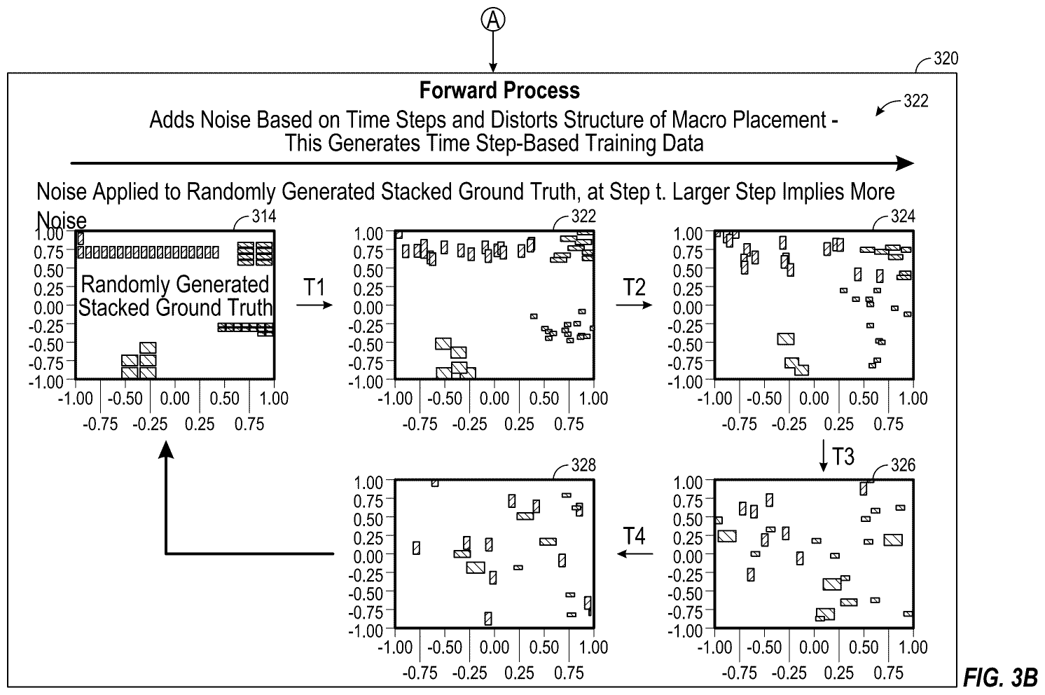

FIGS. 3A-3B illustrate the generation 300 of a training data set for training a generative artificial intelligence model to generate a floorplan representing a layout of an integrated circuit, according to aspects of the present disclosure.

As illustrated, to generate a training data set, a data generator may, at block 310, generate a ground-truth data set 312 including a plurality of synthetic integrated circuit designs 314 including circuit blocks (e.g., circuit blocks 108 discussed above with respect to FIG. 1) of different types. For the purposes of initially training a generative artificial intelligence model to generate floorplans representing valid candidate layouts of an integrated circuit, the synthetic integrated circuit designs 314 may be treated as ground-truth floorplans which the generative artificial intelligence model may use as a training objective. Each of the synthetic integrated circuit designs 314 in the ground-truth data set 312 may be structured such that circuit blocks are stacked, aligned, spaced, and placed along the boundary of a floorplan in various configurations. Generally, the same type of circuit block may be clustered so that a synthetic integrated circuit design 314 includes groups of any number of a particular type of circuit block in a particular region of the floorplan.

In some aspects, to generate these synthetic integrated circuit designs based on which the training data set is generated, a synthetic data generator used to generate the ground-truth data set 312 at block 310 may generate a floorplan boundary representing the floorplan on which other circuit blocks may be positioned. The floorplan boundary may be represented by coordinate values defining the boundaries of a rectangle (or other geometric shapes on which an integrated circuit can be formed). Within this boundary, n overlapping polygons may be generated. Each of the n overlapping polygons may be smaller than the floorplan boundary. The boundary and overlap between the n overlapping polygons may be subtracted to generate a plurality of locations in which macros representing various circuit blocks of an integrated circuit can be positioned. These locations may be converted into different types of macros with different geometric constraints (e.g., movability features), and an edge along which no macros are located may be converted into an I/O port macro for the synthetic integrated circuit design.

At block 320, the ground-truth data set 312 generated at block 310 may be distorted over a plurality of time steps for use in training a generative artificial intelligence model to generate valid floorplans for an integrated circuit design (e.g., the generative artificial intelligence model 200 illustrated in FIG. 2). To generate distorted samples 322, 324, 326, and 328 (amongst others), a ground-truth synthetic integrated circuit design 314 may be selected and distorted at time step TI to generate a first distorted sample 322. Generally, to generate the first distorted sample 322, random noise may be added to the positioning data (e.g., to an x coordinate and a y coordinate defining the position of a reference location of a circuit block) associated with one or more circuit blocks in the ground-truth synthetic integrated circuit design 312 so that the first distorted sample 322 is, unlike the ground-truth synthetic integrated circuit design 312, not a valid floorplan for the integrated circuit. Similar distortion processes may be performed at time step T2 on the first distorted sample 322 to generate a second distorted sample 324, at time step T3 on the second distorted sample 324 to generate a third distorted sample 326, and at time step T4 on the third distorted sample 326 to generate a fourth distorted sample 328.

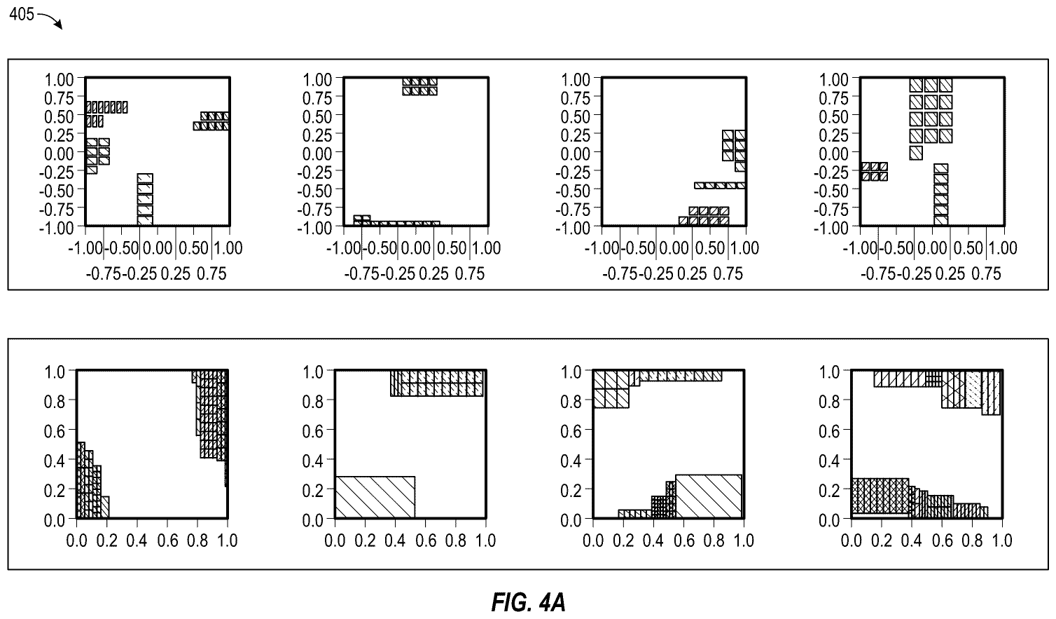

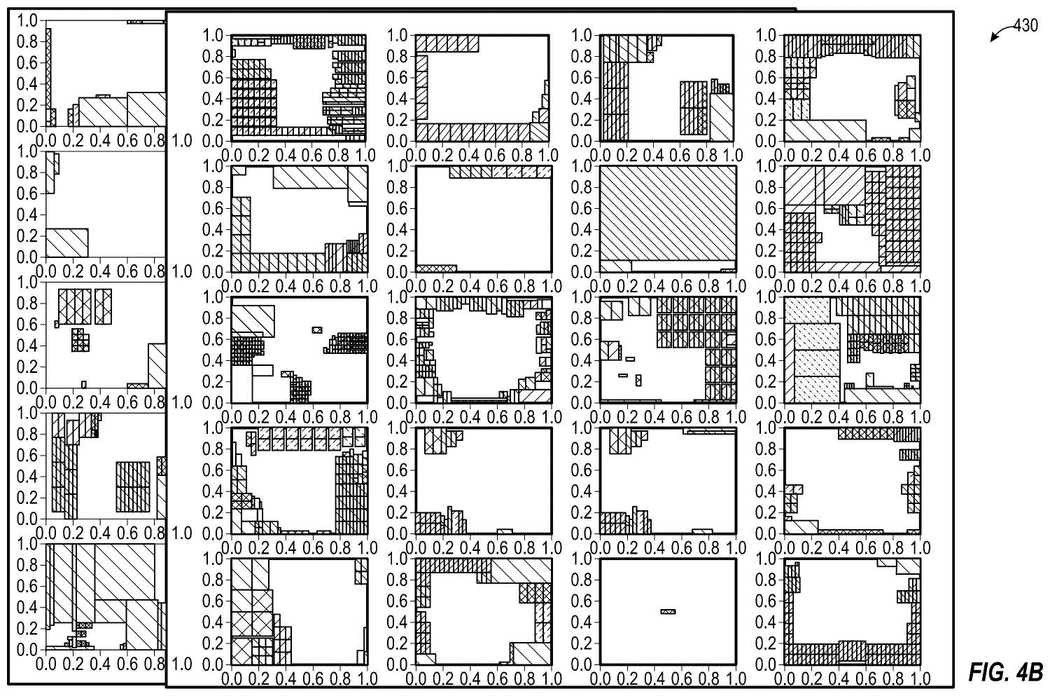

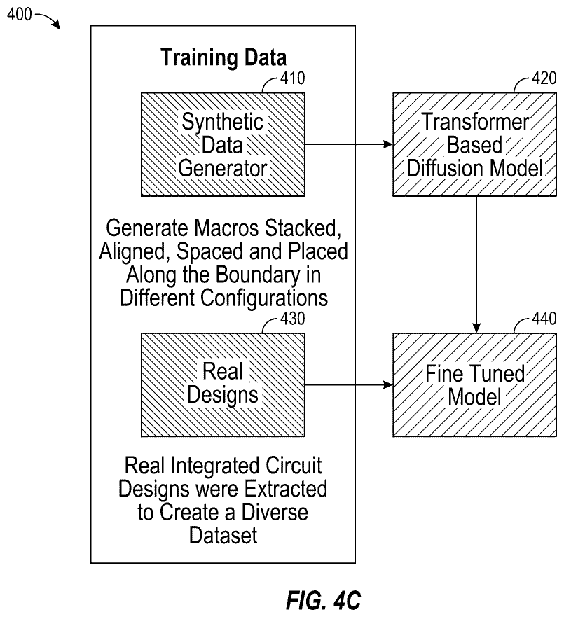

FIGS. 4A-4C illustrate a pipeline 400 for training and finetuning a generative artificial intelligence model for generating a floorplan representing a layout of an integrated circuit, according to aspects of the present disclosure.

As illustrated, the pipeline 400 may begin with generating a training data set 405 using the synthetic data generator 410. The synthetic data generator 410 may generate this training data set based on the techniques discussed above with respect to FIGS. 3A-3B. Using the training data set generated by the synthetic data generator 410, a generative artificial intelligence model 420 (illustrated herein as a transformer-based diffusion model, though it should be recognized that other types of generative artificial intelligence models that can de-noise data to generate, or at least approximate, a ground-truth input may be contemplated herein) may be trained to predict the amount of noise added in each time step to a prior input data set and learn the structure of how different circuit blocks are stacked, aligned, and spaced (and correspondingly learn how to remove noise from a random input over a plurality of time steps in order to generate a floorplan representing a valid layout of an integrated circuit which can be used for testing and/or fabrication processes).

The generative artificial intelligence model 420 may subsequently be tuned into a fine-tuned model 440 based on real integrated circuit designs 430. By fine-tuning the generative artificial intelligence model 420 based on real integrated circuit designs 430, the pipeline 400 may introduce a level of real-life grounding into the inferences generated by the fine-tuned model 440. The real-life grounding may allow for the fine-tuned model 440 to understand features of how real-life integrated circuits are designed so that such real-world knowledge can be incorporated into the predictions generated by the fine-tuned model 440.

### Example Operations for Training and Using Generative Artificial Intelligence Models to Generate Floorplans Representing Layouts of an Integrated Circuit

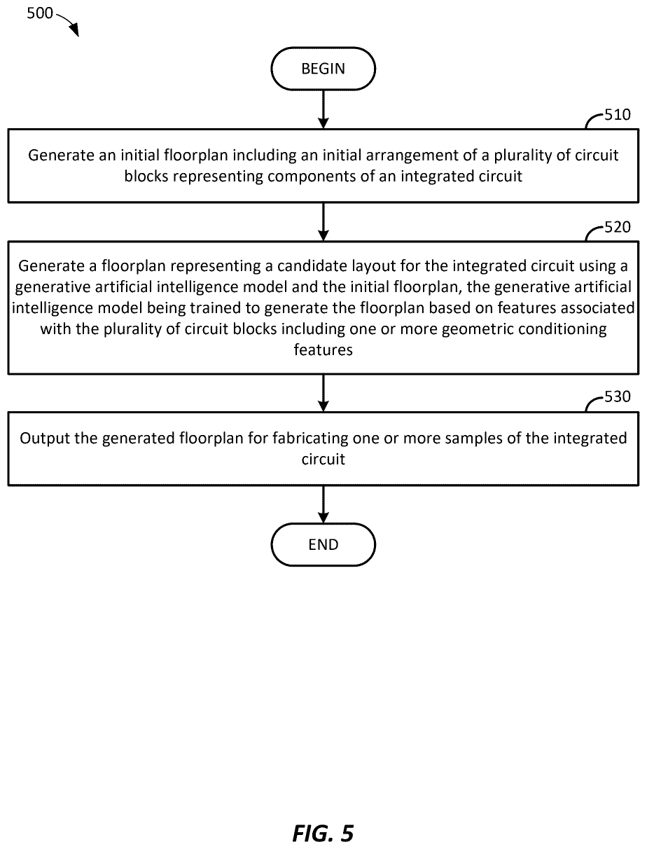

FIG. 5 illustrates example operations for generating a floorplan representing a layout of an integrated circuit using a generative artificial intelligence model, according to aspects of the present disclosure. The operations 500 may be performed by a device on which a generative artificial intelligence model can be deployed, such as a smartphone, a tablet computer, a laptop computer, a desktop, a server, a cloud compute instance hosted in a distributed computing environment, or the like.

As illustrated, the operations 500 begin at block 510 with generating an initial floorplan including an initial arrangement of a plurality of circuit block representing components of an integrated circuit. In some aspects, the initial floorplan may be generated by a circuit block placer which generates an arrangement (e.g., placement of each of a plurality of circuit blocks) based on a defined objective (e.g., connectivity and/or wirelength minimization, or at least reduction, between different circuit blocks).

At block 520, the operations 500 proceed with generating a floorplan representing a candidate layout for the integrated circuit using a generative artificial intelligence model and the initial floorplan. Generally, the generative artificial intelligence model may be trained to generate the floorplan based on features associated with the plurality of circuit blocks, including one or more geometric conditioning features.

In some aspects, each circuit block is associated with spatial dimension features and the geometric conditioning features. Generally, the spatial dimension features may include spatial positioning features, such as a horizontal and vertical coordinate at which a reference point for the circuit block (e.g., a corner of the circuit block) is located, and dimensional features, such as the width and height of a circuit block (which may be scaled relative to a larger circuit block representing the boundaries of a floorplan for an integrated circuit). Generally, the geometric conditioning features associated with a circuit block includes features identifying a type of the circuit block and whether the circuit block is movable. The type of the circuit block may include a special type associated with the floorplan itself and a variety of other types specifying different types of functional components with which a circuit block is associated, such as efficiency cores, performance cores, GPUs, NPUs, caches, and the like, or more granular features of components of an SoC such as particular types of mathematical processing hardware, SRAM cells, or the like.

In some aspects, the plurality of circuit blocks comprise a plurality of input/output ports. The plurality of input/output ports may be combined into a single block disposed on a boundary of the floorplan. In some aspects, the block representing the plurality of input/output ports may be deemed a fixed block, the location of which may not be adjusted by the generative artificial intelligence model.

In some aspects, generating the floorplan representing the candidate layout for the integrated circuit comprises determining a location, over a plurality of iterations of inferencing using the generative artificial intelligence model, for at least one circuit block of the plurality of circuit blocks such that the circuit blocks are aligned relative to a boundary of the floorplan.

In some aspects, each iteration of inferencing using the generative artificial intelligence model applies changes to positional data for one or more circuit blocks based on reducing an amount of noise in a Euclidean space representation of the floorplan, noise being represented by locations of circuit blocks that are neither on the boundary of the floorplan nor adjacent to circuit blocks on the boundary of the floorplan.

At block 530, the operations 500 proceed with outputting the generated floorplan for fabricating one or more samples of the integrated circuit.

In some aspects, the generative artificial intelligence model comprises a diffusion model. Within the diffusion model, the input of a random floorplan (or other floorplan that does not comply with positional rules or PPA specifications for the integrated circuit) may be considered a noisy input that is to be denoised by the diffusion model until a valid floorplan is generated.

In some aspects, the generative artificial intelligence model may be trained to generate the floorplan such that the plurality of circuit blocks do not overlap.

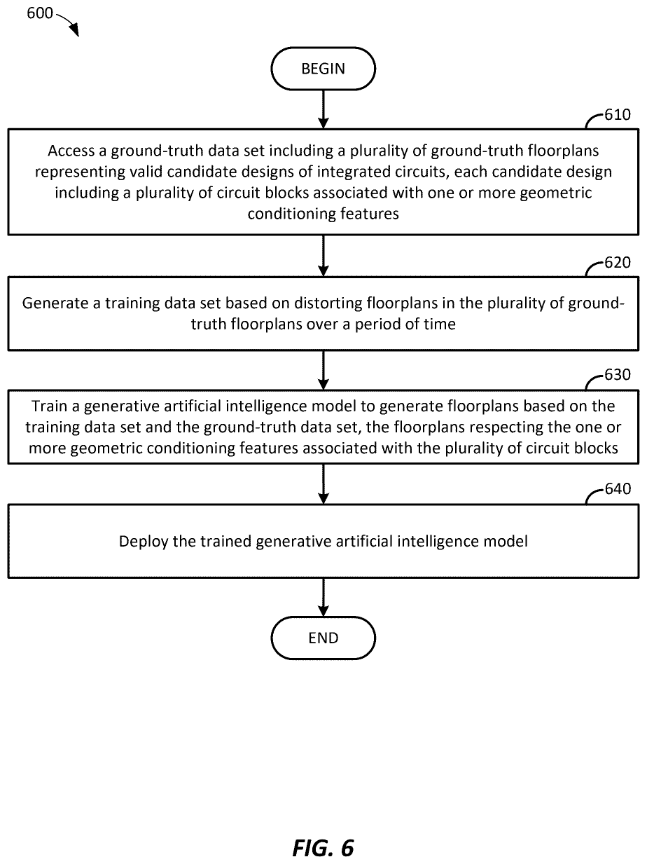

FIG. 6 illustrates example operations 600 for training a generative artificial intelligence model to generate a floorplan representing a layout of an integrated circuit, according to aspects of the present disclosure. The operations 600 may be performed by a device on which a generative artificial intelligence model can be trained, such as a server computer, a cloud compute instance hosted in a distributed computing environment, or the like.

As illustrated, the operations 600 begin at block 610 with accessing a ground-truth data set including a plurality of ground-truth floorplans representing valid candidate designs of integrated circuits. Generally, each candidate design includes a plurality of circuit blocks associated with one or more geometric conditioning features.

At block 620, the operations 600 proceed with generating a training data set based on distorting floorplans in the plurality of ground-truth floorplans over a period of time.

In some aspects, the plurality of ground-truth floorplans in the ground-truth data set comprises circuit blocks randomly aligned, spaced, and stacked along a boundary of the floorplan. To generate the training data set, noise may be applied to change a position of at least one circuit block of the plurality of circuit blocks. This noise, or other random distortions, may be applied to positions of circuit blocks in the ground-truth floorplans over a plurality of time steps. Generally, the distorted floorplans included in the training data set may represent invalid designs for the integrated circuit, such as designs in which at least one circuit block in the floorplan is either not located on a perimeter or adjacent to a circuit block located on the perimeter of the floorplan.

At block 630, the operations 600 proceed with training a generative artificial intelligence model to generate floorplans based on the training data set and the ground-truth data set, the floorplans respecting the one or more geometric conditioning features associated with the plurality of circuit blocks.

In some aspects, training the generative artificial intelligence model comprises training the generative artificial intelligence model to reduce an amount of noise in a Euclidean representation of a floorplan. In some aspects, the noise may be represented by circuit blocks neither located on a boundary of the floorplan nor adjacent to a circuit block located on the boundary of the floorplan. In some aspects, reductions in the amount of noise in the Euclidean representation of the floorplan may allow for the generative artificial intelligence model to learn how to replicate, or at least approximate, the style in which integrated circuits are laid out (e.g., in terms of circuit block (macro) placement) manually. For example, the style in which these integrated circuits are laid out may allow for a maximization, or at least increase, in convex space for cell placement and for stacking and alignment of circuit blocks in a manner that minimizes, or at least reduces, a likelihood that PPA specifications for the integrated circuit are not violated.

In some aspects, training the generative artificial intelligence model further comprises tuning the trained generative artificial intelligence model based on design layouts of historical integrated circuits (e.g., real integrated circuit designs 430 of FIGS. 4B and 4C).

At block 640, the operations 600 proceed with deploying the trained generative artificial intelligence model.

### Example Processing Systems for Training and Using Generative Artificial Intelligence Models to Generate Floorplans Representing Layouts of an Integrated Circuit

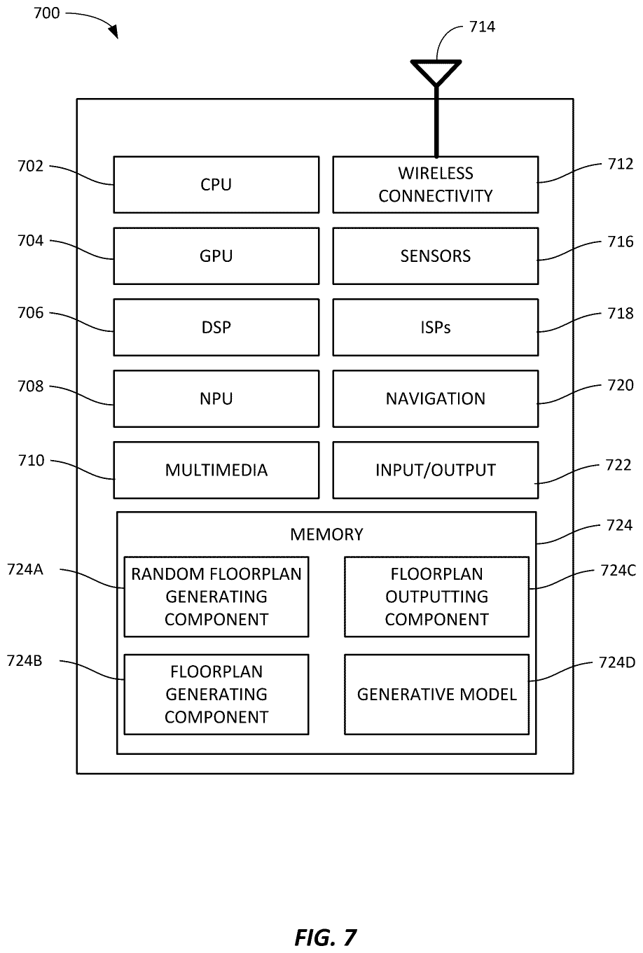

FIG. 7 depicts an example processing system 700 for generating floorplans representing layouts of an integrated circuit using a generative artificial intelligence model, such as described herein for example with respect to FIG. 5.

The processing system 700 includes a central processing unit (CPU) 702, which in some examples may be a multi-core CPU. Instructions executed at the CPU 702 may be loaded, for example, from a program memory associated with the CPU 702 or may be loaded from a memory partition (e.g., of a memory 724).

The processing system 700 also includes additional processing components tailored to specific functions, such as a graphics processing unit (GPU) 704, a digital signal processor (DSP) 706, a neural processing unit (NPU) 708, and a connectivity component 712.

An NPU, such as the NPU 708, is generally a specialized circuit configured for implementing control and arithmetic logic for executing machine learning algorithms, such as algorithms for processing artificial neural networks (ANNs), deep neural networks (DNNs), random forests (RFs), and the like. An NPU may sometimes alternatively be referred to as a neural signal processor (NSP), tensor processing unit (TPU), neural network processor (NNP), intelligence processing unit (IPU), vision processing unit (VPU), or graph processing unit.

NPUs, such as the NPU 708, are configured to accelerate the performance of common machine learning tasks, such as image classification, machine translation, object detection, and various other predictive models. In some examples, a plurality of NPUs may be instantiated on a single chip, such as a system on a chip (SoC), while in other examples such NPUs may be part of a dedicated neural-network accelerator.

NPUs may be optimized for training or inference, or in some cases configured to balance performance between both. For NPUs that are capable of performing both training and inference, the two tasks may still generally be performed independently.

NPUs designed to accelerate training are generally configured to accelerate the optimization of new models, which is a highly compute-intensive operation that involves inputting an existing dataset (often labeled or tagged), iterating over the dataset, and then adjusting model parameters, such as weights and biases, in order to improve model performance. Generally, optimizing based on a wrong prediction involves propagating back through the layers of the model and determining gradients to reduce the prediction error.

NPUs designed to accelerate inference are generally configured to operate on complete models. Such NPUs may thus be configured to input a new piece of data and rapidly process this new piece through an already trained model to generate a model output (e.g., an inference).

In some implementations, the NPU 708 is a part of one or more of the CPU 702, the GPU 704, and/or the DSP 706. These may be located on a user equipment (UE) in a wireless communication system or another computing device.

In some examples, the connectivity component 712 may include subcomponents, for example, for third generation (3G) connectivity, fourth generation (4G) connectivity (e.g., Long-Term Evolution (LTE)), fifth generation (5G) connectivity (e.g., New Radio (NR)), Wi-Fi connectivity, Bluetooth connectivity, and other wireless data transmission standards. The connectivity component 712 may be further coupled to one or more antennas 714.

The processing system 700 may also include one or more sensor processing units 716 associated with any manner of sensor, one or more image signal processors (ISPs) 718 associated with any manner of image sensor, and/or a navigation processor 720, which may include satellite-based positioning system components (e.g., GPS or GLONASS) as well as inertial positioning system components.

The processing system 700 may also include one or more input and/or output devices 722, such as screens, touch-sensitive surfaces (including touch-sensitive displays), physical buttons, speakers, microphones, and the like.

In some examples, one or more of the processors of the processing system 700 may be based on an ARM or RISC-V instruction set.

The processing system 700 also includes the memory 724, which is representative of one or more static and/or dynamic memories, such as a dynamic random access memory, a flash-based static memory, and the like. In this example, the memory 724 includes computer-executable components, which may be executed by one or more of the aforementioned processors of the processing system 700.

In particular, in this example, the memory 724 includes random floorplan generating component 724A, a floorplan generating component 724B, a floorplan outputting component 724C, and a generative model 724D. The depicted components, and others not depicted, may be configured to perform various aspects of the methods described herein.

Generally, the processing system 700 and/or components thereof may be configured to perform the methods described herein.

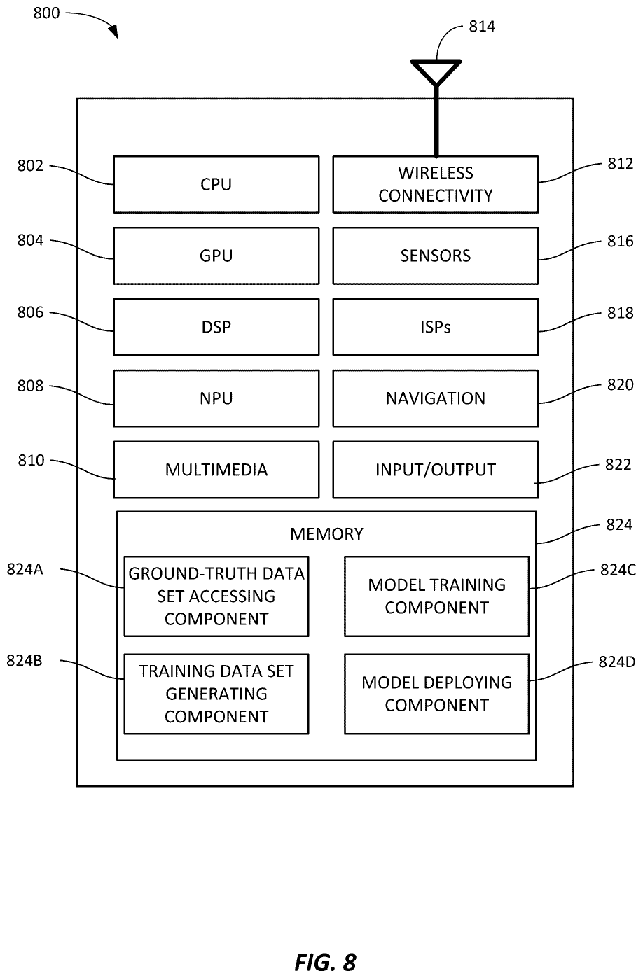

FIG. 8 depicts an example processing system 800 for training a generative artificial intelligence model to generate floorplans representing a layout of an integrated circuit, such as described herein for example with respect to FIG. 6.

The processing system 800 includes a central processing unit (CPU) 802, which in some examples may be a multi-core CPU. Instructions executed at the CPU 802 may be loaded, for example, from a program memory associated with the CPU 802 or may be loaded from a memory partition (e.g., of a memory 824).

The processing system 800 also includes additional processing components tailored to specific functions, such as a graphics processing unit (GPU) 804, a digital signal processor (DSP) 806, a neural processing unit (NPU) 808, and a connectivity component 812.

In some examples, the connectivity component 812 may include subcomponents, for example, for third generation (3G) connectivity, fourth generation (4G) connectivity (e.g., Long-Term Evolution (LTE)), fifth generation (5G) connectivity (e.g., New Radio (NR)), Wi-Fi connectivity, Bluetooth connectivity, and other wireless data transmission standards. The connectivity component 812 may be further coupled to one or more antennas 814.

The processing system 800 may also include one or more sensor processing units 816 associated with any manner of sensor, one or more image signal processors (ISPs) 818 associated with any manner of image sensor, and/or a navigation processor 820, which may include satellite-based positioning system components (e.g., GPS or GLONASS) as well as inertial positioning system components.

The processing system 800 may also include one or more input and/or output devices 822, such as screens, touch-sensitive surfaces (including touch-sensitive displays), physical buttons, speakers, microphones, and the like.

In some examples, one or more of the processors of the processing system 800 may be based on an ARM or RISC-V instruction set.

The processing system 800 also includes the memory 824, which is representative of one or more static and/or dynamic memories, such as a dynamic random access memory, a flash-based static memory, and the like. In this example, the memory 824 includes computer-executable components, which may be executed by one or more of the aforementioned processors of the processing system 800.

In particular, in this example, the memory 824 includes a ground-truth data set accessing component 824A, a training data set generating component 824B, a model training component 824C, and a model deploying component 824D. The depicted components, and others not depicted, may be configured to perform various aspects of the methods described herein.

Generally, the processing system 800 and/or components thereof may be configured to perform the methods described herein.

### Example Clauses

Implementation details of various aspects of the present disclosure are described in the following numbered clauses.

Clause 1: A processor-implemented method for generating a layout of an integrated circuit using machine learning, comprising: generating an initial floorplan including an initial arrangement of a plurality of circuit blocks representing components of the integrated circuit; generate a floorplan representing a candidate layout for the integrated circuit using a generative artificial intelligence model and the initial floorplan, the generative artificial intelligence model being trained to generate the floorplan based on features associated with the plurality of circuit blocks including one or more geometric conditioning features; and outputting the generated floorplan for fabricating one or more samples of the integrated circuit.

Clause 2: The method of Clause 1, wherein each circuit block is associated with spatial dimension features and the geometric conditioning features, and wherein the geometric conditioning features associated with a circuit block comprise features identifying a type of the circuit block and whether the circuit block is movable.

Clause 3: The method of Clause 1 or 2, wherein generating the floorplan representing the candidate layout for the integrated circuit comprises determining a location, over a plurality of iterations of inferencing using the generative artificial intelligence model, for at least one circuit block of the plurality of circuit blocks such that the circuit blocks are aligned relative to a boundary of the floorplan.

Clause 4: The method of Clause 3, wherein each iteration of inferencing using the generative artificial intelligence model applies changes to positional data for one or more circuit blocks based on reducing an amount of noise in a Euclidean space representation of the floorplan, noise being represented by locations of circuit blocks that are neither on the boundary of the floorplan nor adjacent to circuit blocks on the boundary of the floorplan.

Clause 5: The method of any of Clauses 1 through 4, wherein the generative artificial intelligence model comprises a diffusion model.

Clause 6: The method of any of Clauses 1 through 5, wherein the plurality of circuit blocks comprise a plurality of input/output ports, and wherein the plurality of input/output ports are combined into a single block disposed on a boundary of the floorplan.

Clause 7: The method of any of Clauses 1 through 6, wherein the generative artificial intelligence model is trained to generate the floorplan such that the plurality of circuit blocks do not overlap.

Clause 8: A processor-implemented method for generating a layout of an integrated circuit using machine learning, comprising: accessing a ground-truth data set including a plurality of ground-truth floorplans representing valid candidate designs of integrated circuits, each candidate design including a plurality of circuit blocks associated with one or more geometric conditioning features; generating a training data set based on distorting floorplans in the plurality of ground-truth floorplans over a period of time; training a generative artificial intelligence model to generate floorplans based on the training data set and the ground-truth data set, the floorplans respecting the one or more geometric conditioning features associated with the plurality of circuit blocks; and deploying the trained generative artificial intelligence model.

Clause 9: The method of Clause 8, wherein training the generative artificial intelligence model comprises training the generative artificial intelligence model to reduce an amount of noise in an image representing a floorplan and wherein the noise is represented by circuit blocks neither located on a boundary of the floorplan nor adjacent to a circuit block located on the boundary of the floorplan.

Clause 10: The method of Clause 8 or 9, wherein the plurality of ground-truth floorplans in the ground-truth data set comprises circuit blocks randomly aligned, spaced, and stacked along a boundary of a floorplan.

Clause 11: The method of Clause 10, wherein generating the training data set comprises applying noise to change a position of at least one circuit block of the plurality of circuit blocks.

Clause 12: The method of any of Clauses 8 through 11, wherein generating the training data set comprises applying random distortions to positions of circuit blocks in the ground-truth floorplans over a plurality of time steps.

Clause 13: The method of any of Clauses 8 through 12, wherein training the generative artificial intelligence model further comprises tuning the trained generative artificial intelligence model based on design layouts of historical integrated circuits.

Clause 14: A processing system comprising: at least one memory having executable instructions stored thereon; and one or more processors coupled to the at least one memory and configured to execute the executable instructions in order to cause the processing system to perform the operations of any of Clauses 1 through 13.

Clause 15: A processing system comprising means for performing the operations of any of Clauses 1 through 13.

Clause 16: A non-transitory computer-readable medium having executable instructions stored thereon which, when executed by one or more processors, perform the operations of any of Clauses 1 through 13.

### Additional Considerations

The preceding description is provided to enable any person skilled in the art to practice the various aspects described herein. The examples discussed herein are not limiting of the scope, applicability, or aspects set forth in the claims. Various modifications to these aspects will be readily apparent to those skilled in the art, and the generic principles defined herein may be applied to other aspects. For example, changes may be made in the function and arrangement of elements discussed without departing from the scope of the disclosure. Various examples may omit, substitute, or add various procedures or components as appropriate. For instance, the methods described may be performed in an order different from that described, and various steps may be added, omitted, or combined. Also, features described with respect to some examples may be combined in some other examples. For example, an apparatus may be implemented or a method may be practiced using any number of the aspects set forth herein. In addition, the scope of the disclosure is intended to cover such an apparatus or method that is practiced using other structure, functionality, or structure and functionality in addition to, or other than, the various aspects of the disclosure set forth herein. It should be understood that any aspect of the disclosure disclosed herein may be embodied by one or more elements of a claim.

As used herein, the word “exemplary” means “serving as an example, instance, or illustration.” Any aspect described herein as “exemplary” is not necessarily to be construed as preferred or advantageous over other aspects.

As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c).

As used herein, the term “determining” encompasses a wide variety of actions. For example, “determining” may include calculating, computing, processing, deriving, investigating, looking up (e.g., looking up in a table, a database or another data structure), ascertaining, and the like. Also, “determining” may include receiving (e.g., receiving information), accessing (e.g., accessing data in a memory), and the like. Also, “determining” may include resolving, selecting, choosing, establishing, and the like.

The methods disclosed herein comprise one or more steps or actions for achieving the methods. The method steps and/or actions may be interchanged with one another without departing from the scope of the claims. In other words, unless a specific order of steps or actions is specified, the order and/or use of specific steps and/or actions may be modified without departing from the scope of the claims. Further, the various operations of methods described above may be performed by any suitable means capable of performing the corresponding functions. The means may include various hardware and/or software component(s) and/or module(s), including, but not limited to a circuit, an application specific integrated circuit (ASIC), or processor. Generally, where there are operations illustrated in figures, those operations may have corresponding counterpart means-plus-function components with similar numbering.

The following claims are not intended to be limited to the aspects shown herein, but are to be accorded the full scope consistent with the language of the claims. Within a claim, reference to an element in the singular is not intended to mean “one and only one” unless specifically so stated, but rather “one or more.” Unless specifically stated otherwise, the term “some” refers to one or more. No claim element is to be construed under the provisions of 35 U.S.C. § 112(f) unless the element is expressly recited using the phrase “means for” or, in the case of a method claim, the element is recited using the phrase “step for.” All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims.

What is claimed is:

1. A processor-implemented method for generating a layout of an integrated circuit using machine learning, comprising:
generating an initial floorplan including an initial arrangement of a plurality of circuit blocks representing components of the integrated circuit;
generating a floorplan representing a candidate layout for the integrated circuit using a generative artificial intelligence model and the initial floorplan, the generative artificial intelligence model being trained to generate the floorplan based on features associated with the plurality of circuit blocks including one or more geometric conditioning features; and
outputting the generated floorplan for fabricating one or more samples of the integrated circuit.

2. The method of claim 1, wherein each circuit block is associated with spatial dimension features and the geometric conditioning features, and wherein the geometric conditioning features associated with a circuit block comprise features identifying a type of the circuit block and whether the circuit block is movable.

3. The method of claim 1, wherein generating the floorplan representing the candidate layout for the integrated circuit comprises determining a location, over a plurality of iterations of inferencing using the generative artificial intelligence model, for at least one circuit block of the plurality of circuit blocks such that the circuit blocks are aligned relative to a boundary of the floorplan.

4. The method of claim 3, wherein each iteration of inferencing using the generative artificial intelligence model applies changes to positional data for one or more circuit blocks based on reducing an amount of noise in a Euclidean space representation of the floorplan, noise being represented by locations of circuit blocks that are neither on the boundary of the floorplan nor adjacent to circuit blocks on the boundary of the floorplan.

5. The method of claim 1, wherein the generative artificial intelligence model comprises a diffusion model.

6. The method of claim 1, wherein the plurality of circuit blocks comprise a plurality of input/output ports, and wherein the plurality of input/output ports are combined into a single block disposed on a boundary of the floorplan.

7. The method of claim 1, wherein the generative artificial intelligence model is trained to generate the floorplan such that the plurality of circuit blocks do not overlap.

8. A processor-implemented method for generating a layout of an integrated circuit using machine learning, comprising:
accessing a ground-truth data set including a plurality of ground-truth floorplans representing valid candidate designs of integrated circuits, each candidate design including a plurality of circuit blocks associated with one or more geometric conditioning features;
generating a training data set based on distorting floorplans in the plurality of ground-truth floorplans over a period of time;
training a generative artificial intelligence model to generate floorplans based on the training data set and the ground-truth data set, the floorplans respecting the one or more geometric conditioning features associated with the plurality of circuit blocks; and
deploying the trained generative artificial intelligence model.

9. The method of claim 8, wherein training the generative artificial intelligence model comprises training the generative artificial intelligence model to reduce an amount of noise in an image representing a floorplan and wherein the noise is represented by circuit blocks neither located on a boundary of the floorplan nor adjacent to a circuit block located on the boundary of the floorplan.

10. The method of claim 8, wherein the plurality of ground-truth floorplans in the ground-truth data set comprises circuit blocks randomly aligned, spaced, and stacked along a boundary of a floorplan.

11. The method of claim 10, wherein generating the training data set comprises applying noise to change a position of at least one circuit block of the plurality of circuit blocks.

12. The method of claim 8, wherein generating the training data set comprises applying random distortions to positions of circuit blocks in the ground-truth floorplans over a plurality of time steps.

13. The method of claim 8, wherein training the generative artificial intelligence model further comprises tuning the trained generative artificial intelligence model based on design layouts of historical integrated circuits.

14. A processing system, comprising:
at least one memory having executable instructions stored thereon; and
one or more processors configured to execute the executable instructions in order to cause the processing system to:
generate an initial floorplan including an initial arrangement of a plurality of circuit blocks representing components of the integrated circuit;
generate a floorplan representing a candidate layout for the integrated circuit using a generative artificial intelligence model and the initial floorplan, the generative artificial intelligence model being trained to generate the floorplan based on features associated with the plurality of circuit blocks including one or more geometric conditioning features; and
output the generated floorplan for fabricating one or more samples of the integrated circuit.

15. The processing system of claim 14, wherein each circuit block is associated with spatial dimension features and the geometric conditioning features, and wherein the geometric conditioning features associated with a circuit block comprise features identifying a type of the circuit block and whether the circuit block is movable.

16. The processing system of claim 14, wherein to generate the floorplan representing the candidate layout for the integrated circuit, the one or more processors are configured to cause the processing system to determine a location, over a plurality of iterations of inferencing using the generative artificial intelligence model, for at least one circuit block of the plurality of circuit blocks such that the circuit blocks are aligned relative to a boundary of the floorplan.

17. The processing system of claim 16, wherein each iteration of inferencing using the generative artificial intelligence model applies changes to positional data for one or more circuit blocks based on reducing an amount of noise in a Euclidean space representation of the floorplan, noise being represented by locations of circuit blocks that are neither on the boundary of the floorplan nor adjacent to circuit blocks on the boundary of the floorplan.

18. The processing system of claim 14, wherein the generative artificial intelligence model comprises a diffusion model.

19. The processing system of claim 14, wherein the plurality of circuit blocks comprise a plurality of input/output ports, and wherein the plurality of input/output ports are combined into a single block disposed on a boundary of the floorplan.

20. The processing system of claim 14, wherein the generative artificial intelligence model is trained to generate the floorplan such that the plurality of circuit blocks do not overlap.
